(19) United States
(12) Patent Application Publication
(10) Pub. No.: US 2025/0145047 A1
(43) Pub. Date: May 8, 2025

(54) OPERATING SYSTEM FOR BATTERY EXCHANGE STATION AND OPERATING METHOD FOR BATTERY EXCHANGE STATION BY USING SAME

(71) Applicant: Hyundai Kefico Corporation, Gunpo, Gyeonggi-Do (KR)

(72) Inventors: Sil Lo Jin, Gunpo, Gyeonggi-do (KR); Ho Kyung Kim, Hwaseong, Gyeonggi-do (KR); Nam Chul Paik, Anyang, Gyeonggi-do (KR); In Jae Kwak, Hwaseong, Gyeonggi-do (KR); Dae Woo Kim, Gunpo, Gyeonggi-do (KR); Sang Hwan Oh, Hwaseong, Gyeonggi-do (KR); Sang Hoon Kim, Seoul (KR); Hyeong Tae Noh, Gunpo, Gyeonggi-do (KR); Se Hee Byun, Seoul (KR)

(21) Appl. No.: 18/710,674

(22) PCT Filed: Oct. 28, 2022
(86) PCT No.: PCT/KR2022/016703

§ 371 Date: Dec. 31, 2024

(30) Foreign Application Priority Data
Nov. 16, 2021 (KR) 10-2021-0157709

(51) Int. Cl. B60L 53/80; B60L 53/63; B60L 53/67; B60L 53/68; B60L 58/12; B60L 58/18

(52) U.S. Cl. CPC B60L 53/80; B60L 53/63; B60L 53/67; B60L 53/68; B60L 58/12; B60L 58/18; B60L 2240/72; B60L 2240/80; B60L 2270/34

(57) ABSTRACT

The present invention relates to an operating system for a battery exchange station and an operating method for a battery exchange station by using same. The operating system for a battery exchange station, according to an embodiment of the present invention, comprises: a plurality of battery exchange stations; a terminal on which a dedicated application is installed, and which receives an application and service information, input from a user, for a delivery service that performs battery delivery between the plurality of battery exchange stations; and an operating server which communicates with the plurality of battery exchange stations and the terminal, wherein the operating server may determine an arrival station for the battery delivery on the basis of a degree of battery exchange congestion determined for each of the plurality of battery exchange stations.

### TECHNICAL FIELD

The present invention relates to an operating system for a battery exchange station and operating method for a battery exchange station using the same. More particularly, the present invention relates to a system and method for delivering batteries between a plurality of battery exchange stations for efficient operation

### BACKGROUND ART

Electric vehicles are eco-friendly vehicles and are gradually emerging as the mainstream vehicle technology, but there is an inconvenient problem because the time used to charge the battery is longer than the refueling time of an internal combustion engine vehicle. To solve this inconvenience, a battery exchange type operation station may be an alternative.

An exchange type operation station is a station operated by a method in which a charger with multiple slots is provided at the battery exchange station, and when a vehicle arrives at the station, the user inserts its discharged battery into an empty slot and takes out the fully charged battery from the slot. This can shorten the time required to charge the battery.

However, when operating a plurality of battery exchange stations, if the congestion degree of a specific battery exchange station is excessively higher than that of other battery exchange stations, the battery exchange stations with a high congestion degree have the problem of becoming inefficient, such as power usage exceeding the progressive tax application range. Therefore, there is a need for a system and method for solving this problem.

### DISCLOSURE

### Technical Problem

The purpose of the present invention is to provide a system and method for delivering batteries between battery exchange stations in order to efficiently manage a plurality of battery exchange stations.

### Technical Solution

An operating system for a battery exchange station according to an embodiment of the present invention may comprise a plurality of battery exchange stations; a terminal on which a dedicated application is installed, and which receives an application and service information, input from a user, for a delivery service that performs battery delivery between the plurality of battery exchange stations; and an operating server which communicates with the plurality of battery exchange stations and the terminal, wherein the operating server may determine an arrival station for the battery delivery on the basis of a battery exchange congestion degree determined for each of the plurality of battery exchange stations.

Here, the service information may include at least one of a number of batteries requested by the user, an estimated delivery time, a departure station from which delivery begins, and a delivery scheduled area desired by the user.

In this case, the operating server may determine whether the user is a pre-registered user to perform the battery delivery,

In addition, the operating server may determine the battery exchange congestion degree by receiving a congestion parameter from each of the plurality of battery exchange stations.

In this case, the congestion parameter may include at least one of a number of battery exchanges in a predetermined period, an amount of battery charging power in a predetermined period, an expected electricity charge, a number of visiting users, and a number of battery exchange reservations.

In addition, the operating server may compare the battery exchange congestion degree at a departure station where delivery begins with a predetermined reference congestion degree and classify the congestion degree as high or low congestion, and determine the arrival station by applying different criteria according to the classification.

In addition, the operating server may receive a delivery scheduled area desired by the user from the terminal, and when the battery exchange congestion degree at the departure station is high congestion, the operating server may determine whether there is a delivery candidate station with the battery exchange congestion degree lower than the battery exchange congestion degree of the departure station among the battery exchange stations located in the delivery scheduled area.

In addition, the operating server may deny to approve the delivery service application if the delivery candidate station does not exist.

In addition, when there are a plurality of the delivery candidate stations, the operating server may determine the delivery candidate station with the lowest battery exchange congestion degree as the arrival station.

In addition, the operating server may receive a delivery scheduled area from the terminal, and when the battery exchange congestion degree at the departure station is low congestion, the operating server may determine whether there is a delivery candidate station with the battery exchange congestion degree higher than the battery exchange congestion degree of the departure station among the battery exchange stations located in the delivery scheduled area.

In addition, the operating server may deny to approve the delivery service application if the delivery candidate station does not exist.

In addition, when there are a plurality of the delivery candidate stations, the operating server may determine the delivery candidate station with the highest battery exchange congestion degree as the arrival station.

In addition, the operating server may determine a delivery candidate battery based on a state of charge (SOC) of each of a plurality of batteries placed at a departure station where delivery begins.

In addition, the operating server may deny to approve the delivery service application if the delivery candidate battery does not exist.

In addition, the operating server may receive a number of batteries requested by the user from the terminal, compare a number of delivery candidate batteries with the number of batteries requested by the user, and determine a battery to be finally delivered.

In addition, the operating server may detect that battery theft has occurred when an actual delivery time exceeds a threshold time preset based on the estimated delivery time.

A method for operating a battery operation station according to an embodiment of the present invention is a method performed by a processor of an operating server, and the method may comprise an information reception step of receiving, from a user, an application and service information for a delivery service that performs battery delivery between the plurality of battery exchange stations through a terminal; and a determination step of communicating with the plurality of battery exchange stations and the terminal to make a determination related to the battery delivery, wherein the determination step may determine an arrival station for the battery delivery on the basis of a battery exchange congestion degree determined for each of the plurality of battery exchange stations.

Here, the information reception step may determine whether the user is a pre-registered user to perform the battery delivery, and receive, as the service information, at least one of a number of batteries requested by the user, an estimated delivery time, a departure station from which delivery is going to be begun, and a delivery scheduled area desired by the user.

In this case, the determination step may compare the battery exchange congestion degree at the departure station with a predetermined reference congestion degree and classify the congestion degree as high or low congestion, and determine the arrival station by applying different criteria according to the classification.

In addition, when the battery exchange congestion degree at the departure station is high congestion, the determination step may determine whether there is a delivery candidate station with the battery exchange congestion degree lower than the battery exchange congestion degree of the departure station among the battery exchange stations located in the delivery scheduled area. When the battery exchange congestion degree at the departure station is low congestion, the determination step may determine whether there is the delivery candidate station with the battery exchange congestion degree higher than the battery exchange congestion degree of the departure station among the battery exchange stations located in the delivery scheduled area.

In addition, the determination step may deny to approve the delivery service application if the delivery candidate station does not exist.

In addition, the determination step may determine a delivery candidate battery based on a state of charge (SOC) of each of a plurality of batteries placed at a departure station where delivery begins.

In addition, the determination step may deny to approve the delivery service application if the delivery candidate battery does not exist.

Meanwhile, the operating method of the battery exchange station according to an embodiment of the present invention may further comprise a theft detection step of detecting that battery theft has occurred when an actual delivery time exceeds a threshold time preset based on the estimated delivery time.

### Advantageous Effects

According to the present invention, a method for delivering batteries between respective battery station and a system using the method may be constructed, thereby capable of controlling the battery circulation rate and user utilization rate of each battery station. Therefore, there is an advantage of being able to efficiently manage a plurality of battery exchange stations.

### DESCRIPTION OF DRAWINGS

FIG. 1 shows a configuration of an operating system of a battery exchange station according to an embodiment of the present invention.

FIGS. 2A to 2C show a detailed configuration of each component in FIG. 1.

FIG. 3 is a flowchart showing a flow of a method for operating a battery exchange station according to an embodiment of the present invention.

FIG. 4 is a flowchart showing a detailed flow of an information reception step and determination step in FIG. 3.

FIG. 5 is a flowchart showing a detailed flow of a theft detection step in FIG. 3.

### MODE FOR INVENTION

Hereinafter, an embodiment of the present invention will be described in detail with reference to the accompanying drawings.

The present invention may be variously modified and may have various embodiments, and particular embodiments illustrated in the drawings will be specifically described below. The description of the embodiments is not intended to limit the present invention to the particular embodiments, but it should be interpreted that the present invention is to cover all modifications, equivalents and alternatives falling within the spirit and technical scope of the present invention.

In the description of the present invention, the terms such as first and second may be used to describe various components, but the components should not be limited by the terms. These terms are used only to distinguish one component from another component. For example, a first component may be named a second component, and similarly, the second component may also be named the first component, without departing from the scope of the present invention.

The term “and/or” may include a combinations of a plurality of the related and listed items or any item of a plurality of the related and listed items.

When one component is described as being “coupled” or “connected” to another component, it should be understood that one component can be coupled or connected directly to another component, and an intervening component can also be present between the components. When one component is described as being “coupled directly to” or “connected directly to” another component, it should be understood that no intervening component is present between the components.

The terms used herein is used for the purpose of describing particular embodiments only and is not intended to limit the present invention. Singular expressions may include plural expressions unless clearly described as different meanings in the context.

In the specification, it will be further understood that the terms “comprise” and “include” specify the presence of stated features, integers, steps, operations, elements, components, and/or combinations thereof, but do not preclude in advance the possibility of the presence or addition of one or more other features, integers, steps, operations, elements, components, and/or combinations.

Unless otherwise defined, all terms used herein, including technical or scientific terms, may have the same meaning as commonly understood by those skilled in the art to which the present disclosure pertains. The terms such as those defined in a commonly used dictionary may be interpreted as having meanings consistent with meanings in the context of related technologies and may not be interpreted as ideal or excessively formal meanings unless explicitly defined in the present application.

Further, the following embodiments are provided to more completely explain the present invention to those skilled in the art, and shapes and sizes of elements illustrated in the drawings may be exaggerated for a more apparent description.

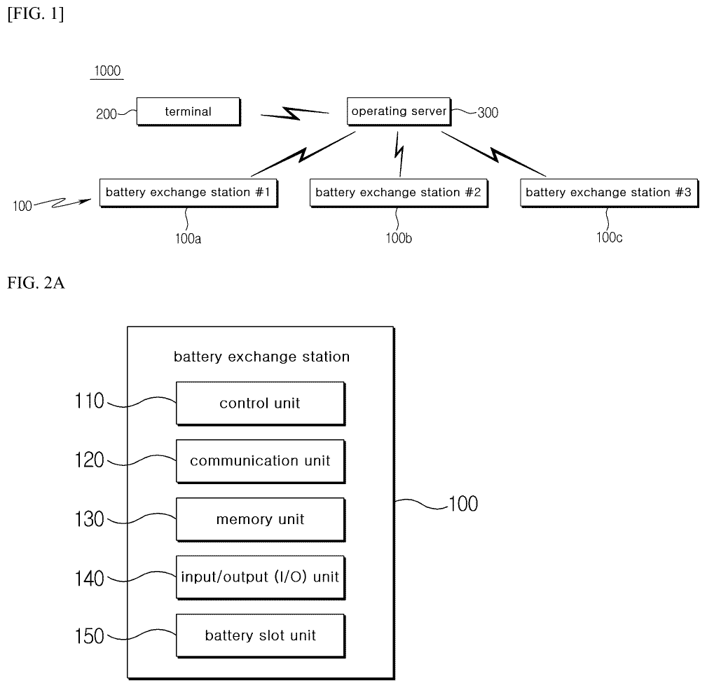

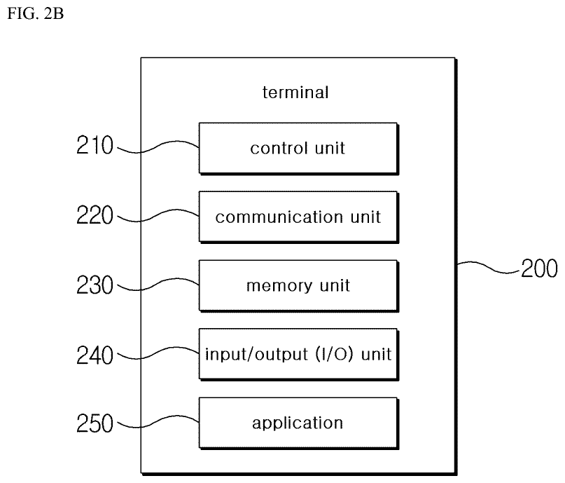

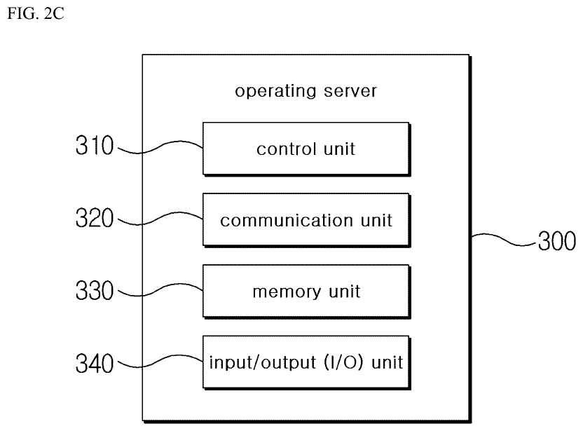

FIG. 1 shows a configuration of an operating system 1000 of a battery exchange station according to an embodiment of the present invention, and FIGS. 2A to 2C show an internal block diagram of each component in FIG. 1.

Referring to FIGS. 1 and 2A to 2C, the operating system 1000 of a battery exchange station according to an embodiment of the present invention may include a plurality of battery exchange stations 100, a terminal 200, and an operating server 300.

The plurality of battery exchange stations 100 are stations equipped with facilities to charge the batteries of an electric vehicle, and may be referred to as an exchange station in the sense that it is a place where the operator of the electric vehicle exchanges his or her discharged battery with a charged battery. Alternatively, it may be referred to as a charging station in the sense that it is a place to charge the discharged battery left behind by the operator of the electric vehicle.

FIG. 1 shows three different battery exchange stations 100a, 100b, and 100c, but the number of battery exchange stations 100 managed by the operating server 300, which will be described later, is not fixed but is flexible. Thus, this point is clear from the point of view of those skilled in the art.

The battery exchange station 100 may include a control unit 110, a communication unit 120, a memory unit 130, an input/output (I/O) unit 140, and a battery slot unit 150.

The control unit 110 may control each component of the battery exchange station 100. The control unit 110 may be any of various controllers that may perform operations by executing computer program instructions, such as a CPU, MCU, microcontroller, or microprocessor.

For example, the control unit 110 may function as a communication module together with the communication unit 120 to control transmission and reception of information between the terminal 200 and the operating server 300. The communication unit 120 is a component that may communicate with other components via wired and/or wirelessly.

Alternatively, for example, the control unit 110 may function as a memory module together with the memory unit 130 and control to load data stored in the memory unit 130 or store new data. The memory unit 130 may include volatile memory and non-volatile memory. For example, it may be at least one of various storage media such as semiconductor memory such as RAM, ROM, and flash memory, magnetic disk, and optical disk. The memory unit 130 may be built into the control unit 110 or may be installed separately from the control unit 110.

Alternatively, for example, the control unit 110 may function as an input/output module together with the input/output unit 140 to control input and output of data. The input/output module may perform input/output of various input signals and output signals. For example, the input/output unit 140 may be configured to include an input/output interface (not shown) and receive input from a user. Alternatively, the input/output unit 140 may further include an output interface (not shown) such as a display for displaying information.

Alternatively, for example, the control unit 110 may function as a charging module together with a battery slot unit 150. The battery slot unit 150 may include a plurality of battery slots. The battery slot may refer to a space where the battery is inserted. The control unit 110 may detect that the discharged battery is inserted into the battery slot and control an electrical connection between the battery slot unit 150 and the discharged battery so that power is supplied to the discharged battery. To this end, the battery slot unit 150 may further include components such as a converter that converts external power into battery charging power and a switch that turns on and off charging of the battery.

The terminal 200 may receive delivery service application information and service information for battery delivery between the plurality of battery exchange stations 100 from the user. The terminal 200 may be a smart phone on which a dedicated application 250 (hereinafter referred to as a ‘delivery application’) related to the battery delivery service may be installed.

The user may apply for delivery service by running the delivery application 250 and enter service information related to delivery. Here, the delivery service refers to a service in which the user withdraws the battery from the battery station (departure station) at the departure point and transports the battery to the battery station (arrival station) at the arrival point.

The service information may include at least one of the number of batteries requested by the user, an estimated delivery time, a departure station from which delivery begins, and a delivery scheduled area desired by the user. The service information may be entered by the user using the delivery application 250. Alternatively, the service information may be entered using the delivery application 250 at the same time the user applies for the delivery service.

In the embodiment of the present invention, the application for delivery service is described as an application through the terminal 200 using the delivery application 250, but in another embodiment, the user may apply through the input interface at the departure station.

The terminal 200 may include a control unit 210, a communication unit 220, a memory unit 230, an input/output (I/O) unit 240, and an application 250.

The control unit 210 may control each configuration of the terminal 200. The control unit 210 may be any of various controllers that may perform operations by executing computer program instructions, such as a CPU, MCU, microcontroller, or microprocessor.

For example, the control unit 210 may function as a communication module together with the communication unit 220 to control transmission and reception of information with the operating server 300, which will be described later. The communication unit 220 is a component that may communicate with other components by wired and/or wirelessly.

Alternatively, for example, the control unit 210 may function as a memory module together with the memory unit 230 and control to load data stored in the memory unit 230 or store new data. The memory unit 230 may include volatile memory and non-volatile memory. For example, it may be at least one of various storage media such as semiconductor memory such as RAM, ROM, and flash memory, magnetic disk, and optical disk. The memory unit 230 may be built into the control unit 210 or may be installed separately from the control unit 210.

Alternatively, for example, the control unit 210 may function as an input/output module together with the input/output unit 240 to control input and output of data. The input/output module may perform input/output of various input signals and output signals. For example, the input/output unit 240 may be configured to include an input/output interface (not shown) and receive input from a user. Alternatively, the input/output unit 240 may further include an output interface (not shown) such as a display for displaying information.

Alternatively, for example, the control unit 210 may perform some steps of the delivery service together with the delivery application 250. As an example, the control unit 210 may transmit (transmit by controlling the communication unit 220) the service information entered by the user through the delivery application 250 to the operating server 300, which will be described later. Alternatively, as an example, the control unit 210 may receive delivery completion information, reward (points, coupon, etc.) level information, etc. from the operating server 300 and display them on the delivery application 250. Alternatively, as an example, the control unit 210 may display a warning signal sent when the operating server 300 detects the theft of the battery on the delivery application 250.

Generally, a user removes a discharged battery from his or her vehicle, inserts it into an empty battery slot of the battery exchange station 100, and withdraws a new, fully charged battery. In order to use the battery exchange station 100, the user may initially generate an authentication key using user information and vehicle information. The authentication key may include information such as the user's name, contact information, and type of vehicle driven as user information.

The user may be pre-registered to apply for delivery services. If the user is pre-registered for the delivery service, the user information may further include information on the number of batteries claimed that he or she may deliver himself or herself. In this case, in addition to the general user information, the authentication key may be generated for the first time by further including the requested battery number information, or an authentication key that has already been generated may be reregistered.

In this case, the information on the number of batteries requested for delivery may be specified by the user in consideration of the user's situation when registering the delivery service, or may be arbitrarily specified by the operating server 300, which will be described later.

The operating server 300 may control the overall operation of the plurality of battery exchange stations 100. The operating server 300 may include a control unit 310, a communication unit 320, a memory unit 330, and an input/output (I/O) unit 340.

The control unit 310 may control each configuration of the operating server 300. The control unit 310 may be any of various controllers that may perform operations by executing computer program instructions, such as a CPU, MCU, microcontroller, or microprocessor.

For example, the control unit 310 may function as a communication module together with the communication unit 320 to control transmission and reception of information between each of a plurality of exchange stations and each terminal 200. In other words, the operating server 300 may communicate with each of the plurality of battery exchange stations 100 or each of the plurality of terminals 200 through a network.

Alternatively, for example, the control unit 310 may function as a memory module together with the memory unit 330 and control to load data stored in the memory unit 330 or store new data. The memory unit 330 may include volatile memory and non-volatile memory. For example, it may be at least one of various storage media such as semiconductor memory such as RAM, ROM, and flash memory, magnetic disk, and optical disk. The memory unit 330 may be built into the control unit 310 or may be installed separately from the control unit 310.

Alternatively, for example, the control unit 310 may function as an input/output module together with the input/output unit 340 to control input and output of data. The input/output module may perform input/output of various input signals and output signals. For example, the input/output unit 340 may be configured to include an input/output interface (not shown) and receive input from a user. Alternatively, the input/output unit 340 may further include an output interface (not shown) such as a display for displaying information.

Meanwhile, the operating server 300 may be configured to operate based on cloud hosting.

When a user applies for a delivery service, the operating server 300 may determine whether the user is a user already registered to perform battery delivery. In other words, user authentication of the delivery service may be performed.

In this case, as described above, since the user already registered in the delivery service may be distinguished from general users through an authentication key, the operating server 300 may perform user authentication by identifying the authentication key.

When user authentication is performed, withdrawal of batteries is allowed or prohibited depending on authentication, thereby preventing unregistered users from withdrawing batteries from the battery exchange station 100 without restrictions.

To explain this in more detail, in the battery exchange station 100 (or in the system 1000 of the present invention), if the user is not registered for the delivery service, the user is allowed to withdraw only the number of batteries matching the vehicle model information registered in the authentication key. If batteries that are not needed for vehicle operation are allowed to be withdrawn without restrictions, serious problems with battery supply may occur.

The battery exchange station 100 (or the system 1000 of the present invention) may allow additional withdrawal of batteries based on the number of batteries requested for delivery if the user is registered for the delivery service. More specifically, assume that two sets of batteries are required to operate the vehicle of a user registered for a delivery service. If the number of batteries requested by the user for delivery is five sets, an additional withdrawal of three sets of batteries may be permitted for the delivery service.

The operating server 300 may determine the arrival station of battery delivery based on a degree of the battery exchange congestion (hereinafter, it may be referred to as a ‘congestion degree’) determined for each of the plurality of battery exchange stations 100.

To determine the battery exchange congestion degree, the operating server 300 may receive a congestion degree parameter from each of the plurality of battery exchange stations 100. In this case, the congestion degree parameter may be at least one of the number of battery exchanges in a predetermined period, an amount of battery charging power in a predetermined period, an expected electricity charge, the number of visiting users, and the number of battery exchange reservations.

The operating server 300 may receive the number of battery exchanges (a first congestion parameter) during a recent predetermined period from each of the plurality of battery exchange stations 100 and sort or rank the stations in order of the highest number of battery exchanges. In this case, the number of battery exchanges may be stored as data in each of the plurality of battery exchange stations 100 and then transmitted to the operating server 300.

The operating server 300 may receive the amount of battery charging power (second congestion parameter) for a recent predetermined period from each of the plurality of battery exchange stations 100 and sort or rank the stations in order of the amount of battery charging power. In this case, the amount of battery charging power may be stored as data in each of the plurality of battery exchange stations 100 and then transmitted to the operating server 300.

The operating server 300 may calculate an expected electricity charge amount (third congestion parameter) calculated by considering the electricity progressive tax section from each of the plurality of battery exchange stations 100 and sort or rank the stations in order of the electricity charge amount being higher.

Meanwhile, the operating server 300 may determine the congestion degree of the battery exchange station 100 using the congestion parameter alone. For example, among the battery exchange stations 100 ranked through any one of the first congestion parameter to the third congestion parameter, the battery exchange station 100 with the highest rank may be determined to be a station with the highest congestion degree. In this case, it may be understood that the lower the rank value, the higher the rank is defined, and a station with a rank value of 1 has a higher rank than a station with a rank value of 2.

Alternatively, the operating server 300 may determine the congestion degree of the battery exchange station 100 using two or more of the congestion parameters. For example, the operating server 300 first determines the ranking of the battery exchange station 100 using each of the first to third congestion parameters, and may determine that the battery exchange station 100 has a higher level of congestion as the final rank value obtained by adding the rank determined by each parameter is lower. More specifically, in a first battery exchange station 100a, if the rank determined using the first congestion parameter is 1, the rank determined using the second congestion parameter is 2, and the rank determined using the third congestion parameter is 2, the sum of respective rankings, which is 5, becomes a final ranking value.

In this way, when determining the congestion degree by using multiple parameters simultaneously, there is an advantage that the reliability of determining the congestion degree increases.

Meanwhile, in addition to the first to third congestion parameters, as described above, the number of users using the battery exchange station 100 or the number of battery reservations may be used alone or in combination with other congestion parameters to determine the congestion degree of the battery exchange station 100.

The operating server 300 may compare the battery exchange congestion degree at a departure station where delivery begins with a predetermined reference congestion degree and classify the congestion degree as a high or low congestion degree, and may determine an arrival station at which the delivered battery will arrive by applying different criteria according to the classification.

This will be described in more detail as follows.

The reference congestion degree may be set in advance and stored in the memory unit 330 of the operating server 300. The reference congestion degree may be preset to a specific rank value of the congestion degree.

For example, assume that a baseline congestion degree is preset to a specific rank value of 5. If the congestion degree of the departure station is 3, it may be classified as high congestion. Additionally, if the congestion degree of the departure station is 7, it may be classified as low congestion.

Meanwhile, as described above, the operating server 300 may receive a delivery scheduled area desired by the user from the terminal.

Hereinafter, a method for determining an arrival station by dividing the case where the departure station is classified as high congestion and the case where the departure station is classified as low congestion will be described in detail.

1. A Case where Battery Exchange Congestion at a Departure Station is Classified as High Congestion

The operating server 300 may determine whether there is a delivery candidate station with a congestion degree lower than that of the departure station among the battery exchange stations 100 located in the delivery scheduled area.

If there is only one delivery candidate station, that delivery candidate station may be determined as an arrival station.

If there are a plurality of delivery candidate stations, the operating server 300 may determine the delivery candidate station with the lowest battery exchange congestion as the arrival station.

In this case, if there is no delivery candidate station, the operating server 300 may deny approval of the delivery service application.

Here, denial of approval of a delivery service application may mean that additional withdrawal of batteries is not permitted. In addition, the operating server 300 may inform the user about the denial of approval by transmitting a notification to the terminal that approval of the delivery service application has been denied.

If the arrival station is determined, the battery to be delivered to the arrival station must be determined among the plurality of batteries disposed at the departure station.

The operating server 300 may determine a delivery candidate battery based on the state of charge (SOC) of each of the plurality of batteries disposed at the departure station. More specifically, among the plurality of batteries, a battery whose SOC is less than a predetermined standard SOC may be determined as a delivery candidate battery. In this case, the SOC information of the batteries may be transmitted through communication from the battery exchange station 100 to the operating server 300, and the reference SOC may be set in advance and stored in the memory unit 330 of the operating server 300.

In this case, if there is no delivery candidate battery, the operating server 300 may deny approval of the delivery service application.

Since the operating server 300 has previously received the number of batteries requested by the user from the terminal 200, it may compare the number of batteries determined as delivery candidate batteries with the number of batteries requested by the user to determine the battery to be finally delivered.

More specifically, if the number of delivery candidate batteries is less than or equal to the number of batteries requested, all delivery candidate batteries may be determined as batteries to be finally delivered.

If the number of delivery candidate batteries is greater than the number of batteries requested, battery selection criteria may be set and only the same number of batteries as requested may be determined as batteries to be finally delivered. In this case, it is desirable that the battery selection criteria be such that batteries with a smaller SOC are selected first.

In this way, if batteries with a low SOC are delivered from a battery exchange station with a high congestion degree to a battery exchange station with a low congestion degree, the operation rate of the battery exchange station with a low congestion degree may be increased. Therefore, there is an effect in that a plurality of battery exchange stations may be operated and managed economically in terms of cost. The electricity charge, which accounts for the largest proportion of the costs consumed in operating the battery exchange station, is a progressive tax applied in certain usage sections, and the electricity charge may be reduced by adjusting the operation rate of the plurality of battery exchange stations 100.

Meanwhile, in this embodiment, the delivery candidate station is first determined and then the delivery candidate battery is determined, but the delivery candidate station may be determined after the delivery candidate battery is first determined. The order of determination is irrelevant, but if there is no delivery candidate battery or no delivery candidate station, approval of the delivery service application may be denied without performing further determination. As a result, the time required to approve a delivery service application may be reduced.

2. A Case where Battery Exchange Congestion at a Departure Station is Classified as Low Congestion

The operating server 300 may determine whether there is a delivery candidate station with a congestion degree higher than the congestion degree of the departure station among the battery exchange stations 100 located in the delivery scheduled area.

If there is only one delivery candidate station, that delivery candidate station may be determined as the arrival station.

If there are a plurality of delivery candidate stations, the operating server 300 may determine the delivery candidate station with the highest battery exchange congestion degree as the arrival station.

In this case, if there is no delivery candidate station, the operating server 300 may deny approval of the delivery service application.

If the arrival station is determined, the battery to be delivered to the arrival station must be determined among the plurality of batteries placed at the departure station.

The operating server 300 may determine, among the plurality of batteries, a battery whose SOC is greater than or equal to a predetermined reference SOC as a delivery candidate battery. In this case, the SOC information of the batteries may be transmitted through communication from the battery exchange station 100 to the operating server 300, and the reference SOC may be set in advance and stored in the memory unit 330 of the operating server 300.

In this case, if there is no delivery candidate battery, the operating server 300 may deny approval of the delivery service application.

Since the operating server 300 has previously received the number of batteries requested by the user from the terminal 200, it may compare the number of batteries determined as delivery candidate batteries with the number of batteries requested by the user to determine the battery to be finally delivered.

More specifically, if the number of delivery candidate batteries is less than or equal to the number of batteries requested, all delivery candidate batteries may be determined as batteries to be finally delivered.

If the number of delivery candidate batteries is greater than the number of batteries requested, battery selection criteria may be set and only the same number of batteries as requested may be determined as batteries to be finally delivered. In this case, it is desirable that the battery selection criteria be such that batteries with a high SOC are selected first.

In this way, when batteries with a high SOC are delivered from the battery exchange station with a low congestion degree to the battery exchange station with a high congestion degree, from the perspective of the battery exchange station with a high congestion degree, there is an advantage in being able to prepare batteries for high utilization without using excessive power. In other words, the battery's circulation rate increases while energy consumption is reduced. Additionally, it is possible to prevent batteries from being left fully charged for long periods of time at the battery exchange station with a low congestion degree. The batteries that are left unused for long periods of time may have their lifespan shortened.

Meanwhile, in this embodiment, the delivery candidate station is first determined and then the delivery candidate battery is determined, but the delivery candidate station may be determined after the delivery candidate battery is first determined. The order of determination is irrelevant, but if there is no delivery candidate battery or no delivery candidate station, approval of the delivery service application may be denied without performing further determination. As a result, the time required to approve a delivery service application may be reduced.

As described so far, there is an advantage in that the plurality of battery exchange stations 100 can be effectively operated by determining the arrival station and the batteries to be delivered based on different criteria depending on whether the departure station is highly congested or low congested.

In a possible embodiment of the present invention, the operating server 300 may detect battery theft that may occur during a delivery service.

More specifically, since the operating server 300 has received an estimated delivery time from the terminal 200, a threshold time may be set in advance based on the estimated delivery time. For example, the threshold time may be set to 100%, 120%, 150%, etc. of the estimated delivery time. However, it is apparent from the perspective of those skilled in the art that the threshold time may be changed depending on an operating policy.

In this case, the operating server 300 may detect that battery theft has occurred when an actual delivery time exceeds the threshold time.

More specifically, for example, the operating server 300 may transmit a first warning to the terminal when the delivery time exceeds a first threshold time set to 100% of the estimated delivery time.

The operating server 300 may transmit a second warning to the terminal when the delivery time exceeds a second threshold time set to 120% of the estimated delivery time. In the secondary warning, the user may be warned that theft may be reported if delivery is delayed any longer without reporting to the operating system 1000.

The operating server 300 may automatically report battery theft when the delivery time exceeds a third threshold time set to 150% of the estimated delivery time.

In this way, since the operating server 300 may detect battery theft, the operation of the battery exchange station 100, including the delivery service, may be maintained stably.

In a possible embodiment of the present invention, the operating server 300 may determine to pay compensation to the user who has performed the delivery service.

More specifically, the operating server 300 may determine to differentially pay compensation according to the recorded data of the user who has performed the battery delivery service. The recorded data may be a rank determined using one or more of a number of batteries delivered, a cumulative delivery distance, and a cumulative delivery time. The recorded data may be calculated by the terminal 200 and transmitted to the operating server 300.

In this case, compensation paid to the user may be resources that may be used at the battery exchange station 100. For example, the reward may be cash, points, premium services, etc.

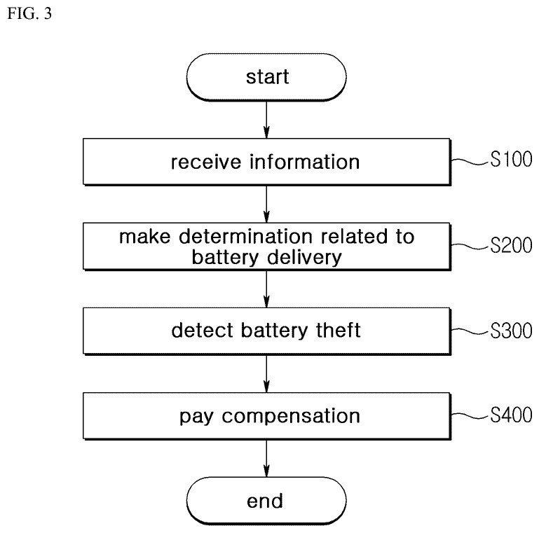

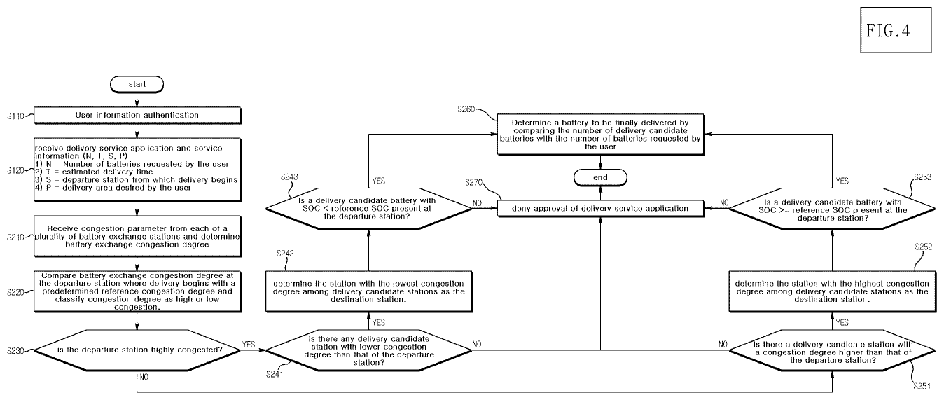

Hereinafter, a method for operating a battery exchange station according to an embodiment of the present invention will be described with reference to FIGS. 3 to 5.

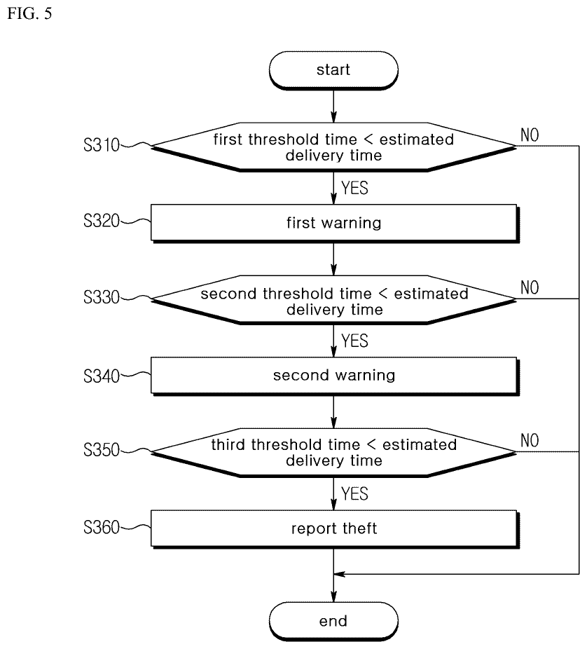

FIG. 3 is a flowchart showing a flow of a method for operating a battery exchange station according to an embodiment of the present invention. FIG. 4 is a flowchart showing a detailed flow of an information reception step and determination step in FIG. 3. FIG. 5 is a flowchart showing a detailed flow of a theft detection step in FIG. 3.

A method for operating a battery exchange station according to an embodiment of the present invention may be performed in the operating server 300 described above.

Referring to FIGS. 3 to 5, the method for operating a battery exchange station according to an embodiment of the present invention may comprise an information reception step (S100) and a determination step (S200).

The information receiving step (S100) is a step of receiving a delivery service application for battery delivery between the plurality of battery exchange stations 100 from the user and receiving service information.

More specifically, in this step (S100), the operating server 300 may determine whether the user is a pre-registered user to perform battery delivery. (S110) That is, user authentication of the delivery service may be performed. In this case, as described above, since the user already registered in the delivery service may be distinguished from general users through an authentication key, the operating server 300 may perform user authentication by identifying the authentication key.

Next, the operating server 300 may receive, as service information, at least one of the number of batteries requested by the user, the estimated delivery time, the departure station from which delivery begins, and the delivery scheduled area. (S120) The service information may be information previously entered by the user using the delivery application 250, or may be information entered using the delivery application 250 at the same time as applying for the delivery service. The service information may be received by communicating with the terminal 200.

The determination step (S200) is a step in which the operating server 300 communicates with the plurality of battery exchange stations 100 and the terminal 200 to make a determination related to battery delivery. For example, determinations related to battery delivery may include determinations of the arrival station and/or determination of the batteries to be delivered.

In this case, in this step (S200), the arrival station of battery delivery may be determined based on the battery exchange congestion degree determined for each of the plurality of battery exchange stations 100.

More specifically, in this step (S200), the operating server 300 may receive a congestion parameter from each of the plurality of battery exchange stations 100 and determine the battery exchange congestion degree. (S210) In this case, the congestion parameter may be at least one of a number of battery exchanges in a predetermined period, an amount of battery charging power in a predetermined period, an expected electricity charge, a number of visiting users, and a number of battery exchange reservations.

Meanwhile, the operating server 300 may determine the congestion degree of the battery exchange station 100 using one or more congestion parameters. This has been explained in detail previously, so redundant explanation will be omitted here.

Next, the operating server 300 may compare the battery exchange congestion degree of the departure station with a predetermined reference congestion degree and classify the congestion degree as high or low congestion. In this case, the operating server 300 may determine the arrival station by applying different criteria according to the above classification.

More specifically, the flow of the operating method when the departure station is classified as highly congested in step S230 is as follows.

If the battery exchange congestion at the departure station is high, it is determined whether there is a delivery candidate station with a battery exchange congestion degree lower than the battery exchange congestion degree at the departure station among the battery exchange stations located in the delivery scheduled area. (S241)

If there is only one delivery candidate station, that delivery candidate station may be determined as the arrival station.

If there are a plurality of delivery candidate stations, the operating server 300 may determine the delivery candidate station with the lowest battery exchange congestion degree as the arrival station. (S242)

In this case, if there is no delivery candidate station, the operating server 300 may deny approval of the delivery service application. (S270) Here, denial of approval of the delivery service application may mean that additional battery withdrawal is not permitted. In addition, the operating server 300 may inform the user about the denial of approval by transmitting a notification to the terminal 200 that approval of the delivery service application has been denied.

Next, the operating server 300 may determine, among the plurality of batteries placed at the departure station, a battery whose SOC is less than a predetermined reference SOC as a delivery candidate battery. (S243)

Here, the SOC information of the batteries may be transmitted through communication from the battery exchange station 100 to the operating server 300, and the reference SOC may be set in advance and stored in the memory unit 330 of the operating server 300.

In this case, if there is no delivery candidate battery, the operating server 300 may deny approval of the delivery service application. (S270)

Since the operating server 300 has previously received the number of batteries requested by the user from the terminal 200, it may compare the number of batteries determined as the delivery candidate batteries with the number of batteries requested by the user to determine the battery to be finally delivered. (S260)

More specifically, if the number of delivery candidate batteries is less than or equal to the number of batteries requested, all delivery candidate batteries may be determined as batteries to be finally delivered. If the number of delivery candidate batteries is greater than the number of batteries requested, battery selection criteria may be set and only the number of batteries requested may be determined as the battery to be finally delivered. In this case, it is desirable to set the battery selection criteria so that batteries with a smaller SOC are selected first.

In this way, if batteries with a low SOC are delivered from the battery exchange station with a high congestion degree to the battery exchange station with a low congestion degree, the operation rate of the battery exchange station with a low congestion degree may be increased. Accordingly, the plurality of battery exchange stations 100 may be operated and managed economically in terms of cost. The electricity charge, which accounts for the largest proportion of the costs consumed in operating the battery exchange station 100, is subject to a progressive tax in certain usage sections, and the electricity charge may be reduced by adjusting the operation rate of the plurality of battery exchange stations 100.

In this embodiment, the delivery candidate station is first determined in step S241, and then the delivery candidate battery is determined in step S243, but the sequence of steps S241 and S243 may be changed. In other words, the order of determination is irrelevant, and if there is no delivery candidate battery or there is no delivery candidate station, approval of the delivery service application may be denied without performing further determination. (S270) Accordingly, the time required to approve delivery service applications may be reduced.

Meanwhile, in the case where the departure station is classified as low congestion in step S230, the flow of the operating method is explained as follows.

If the battery exchange congestion degree at the departure station is low, it is determined whether there is a delivery candidate station with a battery exchange congestion degree higher than the battery exchange congestion degree at the departure station among the battery exchange stations 100 located in the delivery scheduled area. (S251)

If there is only one delivery candidate station, that delivery candidate station may be determined as the arrival station.

If there are a plurality of delivery candidate stations, the operating server 300 may determine the delivery candidate station with the highest battery exchange congestion degree as the arrival station. (S252)

In this case, if there is no delivery candidate station, the operating server 300 may deny approval of the delivery service application. (S270)

Next, the operating server 300 may determine, among the plurality of batteries placed at the departure station, a battery whose SOC is greater than or equal to a predetermined reference SOC as a delivery candidate battery. (S253)

In this case, if there is no delivery candidate battery, the operating server 300 may deny approval of the delivery service application. (S270)

Since the operating server 300 has previously received the number of batteries requested by the user from the terminal 200, it may compare the number of batteries determined as delivery candidate batteries with the number of batteries requested by the user to determine the battery to be finally delivered. (S260)

More specifically, if the number of delivery candidate batteries is less than or equal to the number of batteries requested, all delivery candidate batteries may be determined as batteries to be finally delivered. If the number of delivery candidate batteries is greater than the number of batteries requested, battery selection criteria may be set and only the number of batteries requested may be determined as the battery to be finally delivered. In this case, it is desirable to set the battery selection criteria so that batteries with a high SOC are selected first.

In this way, when batteries with a high SOC are delivered from the battery exchange station with a low congestion degree to the battery exchange station with a high congestion degree, from the perspective of the battery exchange station with a high congestion degree, there is an advantage in being able to prepare batteries for high utilization without using excessive power. In other words, the battery's circulation rate increases while energy consumption is reduced. Additionally, it is possible to prevent batteries from being left fully charged for long periods of time at the battery exchange station with a low congestion degree. The batteries that are left unused for long periods of time may have their lifespan shortened.

In this embodiment, the delivery candidate station is first determined in step S251 and then the delivery candidate battery is determined in step S253, but the sequence of steps S251 and S253 may be changed. In other words, the order of determination is irrelevant, and if there is no delivery candidate battery or there is no delivery candidate station, approval of the delivery service application may be denied without performing further determination. (S270) The time required to approve delivery service applications may be reduced.

Meanwhile, in a possible embodiment of the present invention, a theft detection step (S300) may be further comprised to detect battery theft that may occur during a delivery service.

More specifically, since the operating server 300 has received an estimated delivery time from the terminal 200, a threshold time may be set in advance based on the estimated delivery time. For example, the threshold time may be set to 100%, 120%, 150%, etc. of the estimated delivery time. However, it is apparent from the perspective of those skilled in the art that the threshold time may be changed depending on an operating policy.

In this case, the operating server 300 may detect that battery theft has occurred when an actual delivery time exceeds the threshold time.

To describe the detailed steps of the theft detection step (S300) more specifically, the operating server 300 may determine when the delivery time exceeds the first threshold time set to 100% of the estimated delivery time (S310) and may transmit a first warning to the terminal. (S320)

The operating server 300 may determine that the delivery time exceeds the second threshold time set at 120% of the estimated delivery time (S330) and transmit a secondary warning to the terminal. (S340) In this case, in the secondary warning, the user may be warned that theft may be reported if delivery is delayed any longer without reporting to the operating system 1000.

The operating server 300 may determine that the delivery time exceeds the third threshold time set to 150% of the estimated delivery time (S350) and automatically report the battery theft. (S360)

It is apparent that the second threshold time is greater than the first threshold time, and the third threshold time is greater than the second threshold time.

In this way, since the operating server 300 may detect battery theft, the operation of the battery exchange station 100, including the delivery service, may be maintained stably.

Meanwhile, in a possible embodiment of the present invention, the operating server 300 may further comprise a compensation payment step (S400) of determining to pay compensation to the user who has performed the delivery service.

More specifically, in this step, the operating server 300 may determine to differentially pay compensation according to the recorded data of the user who has performed the battery delivery service. The recorded data may be a rank determined using one or more of a number of batteries delivered, a cumulative delivery distance, and a cumulative delivery time. The recorded data may be calculated by the terminal 200 and transmitted to the operating server 300.

In this case, compensation paid to the user may be resources that may be used at the battery exchange station 100. For example, the reward may be cash, points, premium services, etc.

Meanwhile, a more detailed description of the operating method of the battery exchange station described with reference to FIGS. 3 to 5 may be replaced with the description of the operating system 1000 of the battery exchange station described above.

As described above, according to the present invention, a method for delivering batteries between respective battery station and a system using the method may be constructed, thereby capable of controlling the battery circulation rate and user utilization rate of each battery station. Therefore, there is an advantage of being able to efficiently manage a plurality of battery exchange stations.

Meanwhile, although the present invention has been described with specific embodiments and drawings, the present invention is not limited to the above embodiments, and various modifications and changes may be made by those skilled in the art from these descriptions. Therefore, the technical idea of the present invention should be understood only by the claims, and all equivalent or equivalent modifications thereof shall fall within the scope of the technical idea of the present invention.

1. An operating system for a battery exchange station, comprising
a plurality of battery exchange stations;
a terminal on which a dedicated application is installed, and which receives an application and service information, input from a user, for a delivery service that performs battery delivery between the plurality of battery exchange stations; and
an operating server which communicates with the plurality of battery exchange stations and the terminal,
wherein the operating server determines an arrival station for the battery delivery on the basis of a battery exchange congestion degree determined for each of the plurality of battery exchange stations.

2. The operating system of claim 1, wherein the service information includes at least one of a number of batteries requested by the user, an estimated delivery time, a departure station from which delivery begins, and a delivery scheduled area desired by the user.

3. The operating system of claim 2, wherein the operating server determines whether the user is a pre-registered user to perform the battery delivery.

4. The operating system of claim 1, wherein the operating server determines the battery exchange congestion degree by receiving a congestion parameter from each of the plurality of battery exchange stations.

5. The operating system of claim 4, wherein the congestion parameter includes at least one of a number of battery exchanges in a predetermined period, an amount of battery charging power in a predetermined period, an expected electricity charge, a number of visiting users, and a number of battery exchange reservations.

6. The operating system of claim 1, wherein the operating server compares the battery exchange congestion degree at a departure station where delivery begins with a predetermined reference congestion degree and classifies the congestion degree as high or low congestion, and determines the arrival station by applying different criteria according to the classification.

7. The operating system of claim 6, wherein the operating server receives a delivery scheduled area desired by the user from the terminal, and
wherein when the battery exchange congestion degree at the departure station is high congestion, the operating server determines whether there is a delivery candidate station with the battery exchange congestion degree lower than that of the departure station among the battery exchange stations located in the delivery scheduled area.

8. The operating system of claim 7, wherein the operating server denies to approve the delivery service application if the delivery candidate station does not exist.

9. The operating system of claim 7, wherein when there are a plurality of the delivery candidate stations, the operating server determines the delivery candidate station with the lowest battery exchange congestion degree as the arrival station.

10. The operating system of claim 6, wherein the operating server receives a delivery scheduled area from the terminal, and
wherein when the battery exchange congestion degree at the departure station is low congestion, the operating server determines whether there is a delivery candidate station with the battery exchange congestion degree higher than the battery exchange congestion degree of the departure station among the battery exchange stations located in the delivery scheduled area.

11. The operating system of claim 10, wherein the operating server denies to approve the delivery service application if the delivery candidate station does not exist.

12. The operating system of claim 10, wherein when there are a plurality of the delivery candidate stations, the operating server determines the delivery candidate station with the highest battery exchange congestion degree as the arrival station.

13. The operating system of claim 1, wherein the operating server determines a delivery candidate battery based on a state of charge (SOC) of each of a plurality of batteries placed at a departure station where delivery begins.

14. The operating system of claim 13, wherein the operating server denies to approve the delivery service application if the delivery candidate battery does not exist.

15. The operating system of claim 13, wherein the operating server receives a number of batteries requested by the user from the terminal, compares a number of delivery candidate batteries with the number of batteries requested by the user, and determines a battery to be finally delivered.

16. The operating system of claim 2, wherein the operating server detects that battery theft has occurred when an actual delivery time exceeds a threshold time preset based on the estimated delivery time.

17. A method for operating a plurality of battery exchange stations performed by a processor of an operating server, the method comprising:
an information reception step of receiving, from a user, an application and service information for a delivery service that performs battery delivery between the plurality of battery exchange stations through a terminal; and
a determination step of communicating with the plurality of battery exchange stations and the terminal to make a determination related to the battery delivery,
wherein the determination step determines an arrival station for the battery delivery on the basis of a battery exchange congestion degree determined for each of the plurality of battery exchange stations.

18. The method of claim 17, wherein the information reception step determines whether the user is a pre-registered user to perform the battery delivery, and receives, as the service information, at least one of a number of batteries requested by the user, an estimated delivery time, a departure station from which delivery begins, and a delivery scheduled area desired by the user.

19. The method of claim 18, wherein the determination step compares the battery exchange congestion degree at the departure station with a predetermined reference congestion degree and classifies the congestion degree as high or low congestion, and determines the arrival station by applying different criteria according to the classification.

20. The method of claim 19, wherein when the battery exchange congestion degree at the departure station is high congestion, the determination step determines whether there is a delivery candidate station with the battery exchange congestion degree lower than the battery exchange congestion degree of the departure station among the battery exchange stations located in the delivery scheduled area,
wherein when the battery exchange congestion degree at the departure station is low congestion, the determination step determines whether there is the delivery candidate station with the battery exchange congestion degree higher than the battery exchange congestion degree of the departure station among the battery exchange stations located in the delivery scheduled area.

21. The method of claim 20, wherein the determination step denies to approve the delivery service application if the delivery candidate station does not exist.

22. The method of claim 17, wherein the determination step determines a delivery candidate battery based on a state of charge (SOC) of each of a plurality of batteries placed at a departure station where delivery begins.

23. The method of claim 22, wherein the determination step denies to approve the delivery service application if the delivery candidate battery does not exist.

24. The method of claim 18, further comprising:
a theft detection step of detecting that battery theft has occurred when an actual delivery time exceeds a threshold time preset based on the estimated delivery time.
